(19) United States
(12) Patent Application Publication
(10) Pub. No.: US 2024/0170593 A1
(43) Pub. Date: May 23, 2024

(54) PHOTOVOLTAIC MODULE WITH PATTERN AND PREPARATION METHOD THEREOF

(71) Applicant: CANDO-SOLAR PHOTOELECTRIC TECHNOLOGY (CHANGZHOU) CO., LTD., Changzhou, Jiangsu (CN)

(72) Inventors: Pinru HUANG, Changzhou (CN); Yaolun HUANG, Changzhou (CN); Jiayuan HUANG, Changzhou (CN)

(21) Appl. No.: 17/786,500

(22) PCT Filed: Mar. 24, 2022
(86) PCT No.: PCT/CN2022/082790

§ 371 Date: Jun. 16, 2022

(30) Foreign Application Priority Data
Feb. 25, 2022 (CN) 202210182549.1

(51) Int. Cl. H01L 31/048; H01L 31/0463; H01L 31/18

(52) U.S. Cl. CPC H01L 31/0481; H01L 31/0463; H01L 31/18

(57) ABSTRACT

The present disclosure relates to a photovoltaic module with pattern and a preparation method thereof. The photovoltaic module with pattern includes a photovoltaic cell layer and a transparent encapsulation structure encapsulating the photovoltaic cell layer, patterned gap spaces are provided inside the transparent encapsulation structure for forming a low refractive index region, and refractive index difference between the patterned gap spaces and a physical medium inside the photovoltaic module forms a pattern on a surface of the photovoltaic module. The preparation method thereof is: firstly, preparing the photovoltaic cell layer and various structural layers of an encapsulation structure, and then typesetting and laminating the same into a photovoltaic module.

### CROSS-REFERENCE TO RELATED APPLICATION

The present disclosure claims the priority to the Chinese patent application with the filing number 202210182549.1 filed on Feb. 25, 2022 with the State Intellectual Property Office of China, and entitled “Photovoltaic Module with Pattern and Preparation Method thereof”, the contents of which are incorporated herein by reference in entirety.

### TECHNICAL FIELD

The present disclosure relates to the technical field of photovoltaics, and in particular to a photovoltaic module with pattern and a preparation method thereof.

### BACKGROUND ART

Since 2020, photovoltaics have become more and more close to human life. Besides current common large-scale above-ground or above water power stations, the photovoltaic technology is increasingly applied to different scenes such as roofs of households, building wall surfaces, and roofs of electric vehicles. In addition to the practicability demands for photovoltaic products, people are also starting to pursue the aesthetics and artistry of photovoltaic products more and more.

The US Tesla Company provides a color photovoltaic tile to replace the common roof, the Holland ECN provides a color photovoltaic module for color building, and in China, Hanergy photovoltaics, Changzhou TrinaSolar, and Baoding GAIN SOLAR, a subsidiary of Yingli Group, and so on have made a lot of pioneering explorations on the colorization of building photovoltaics. In recent years, companies such as Xi'an Longi Group and Jinko also put forward color photovoltaic module products, and work on the building photovoltaic market.

Generally, all of the above solutions of color photovoltaic module sacrifice the power generation efficiency of the photovoltaic module, and increase the power generation cost to the extent that the mainstream market cannot accept. Therefore, most of these products exist in the niche market as demonstration projects, and cannot become a mainstream.

All the existing color photovoltaic module solutions form a color pattern by adopting a mode of printing color paint or sputter coating, to improve the aesthetic degree of the module, for example, the Chinese invention patent CN113087406A High-temperature Tempered Colored Photovoltaic Glass Panel and Production Method thereof, and Colored Solar Photovoltaic Module, the Chinese invention patent CN109463011A Colored Photovoltaic Module, and the building color photovoltaic outer facade technology published in Energy Procedia 122 (2017) 175-180. Such a colorization solution of module will cause light shielding and large energy loss, and the power loss ranges in 15%-25%.

### SUMMARY

The technical problem to be solved by the present disclosure is to provide a photovoltaic module with pattern and a preparation method thereof, to reduce the impact of photovoltaic module patterning on the power generation efficiency of the module.

A technical solution adopted by the present disclosure to solve the technical problem thereof is as follows: a photovoltaic module with pattern, including a photovoltaic cell layer and a transparent encapsulation structure encapsulating the photovoltaic cell layer, wherein a patterned gap space is provided inside the transparent encapsulation structure for forming a low refractive index region, and refractive index difference between the patterned gap space and the transparent encapsulation structure forms a pattern on a surface of the photovoltaic module.

It is further defined that the transparent encapsulation structure includes at least one patterned film layer, and the patterned film layer has patterned through holes, grooves or bubbles for forming the patterned gap space.

It is further defined that a side of the patterned gap space has an optical microstructure, for enhancing a pattern effect of a surface of the photovoltaic module.

It is further defined that the transparent encapsulation structure includes at least one patterned film layer, the patterned film layer is a patterned adhesive thin film layer, the patterned adhesive thin film layer has patterned through holes, grooves or bubbles, for forming the patterned gap space, and physical medium layers at two sides of the patterned adhesive thin film layer are non-flowing or low-flowing medium layers at a lamination temperature.

It is further defined that a physical medium layer at a side where the light incident surface of the patterned adhesive thin film layer is located is a non-flowing medium layer, an optical microstructure is provided on a side of the non-flowing medium layer facing the patterned adhesive thin film layer, the optical microstructure is distributed on the whole surface or a partial surface of the non-flowing medium layer, and the partial surface is a surface region corresponding to the patterned gap space.

It is further defined that the patterned adhesive thin film layer has a thickness of 5˜200 μm.

It is further defined that one side of the patterned adhesive thin film layer is provided with a photovoltaic cell layer, and the other side of the patterned adhesive thin film layer is provided with a transparent film layer.

It is further defined that a specific structure of the photovoltaic module with pattern includes, from top to bottom, a front cover plate, an encapsulation adhesive layer, a transparent film layer, a patterned adhesive thin film layer, a photovoltaic cell layer, a patterned adhesive thin film layer, a transparent film layer, an encapsulation adhesive layer, and a rear cover plate; alternatively, a specific structure includes, from top to bottom, a front cover plate, an encapsulation adhesive layer, a transparent film layer, a patterned adhesive thin film layer, a photovoltaic cell layer, an encapsulation adhesive layer, and a rear cover plate; alternatively, a specific structure includes, from top to bottom, a front cover plate, a patterned adhesive thin film layer, a photovoltaic cell layer, the patterned adhesive thin film layer, and a rear cover plate; and alternatively, a specific structure includes, from top to bottom, a front cover plate, a patterned adhesive thin film layer, a photovoltaic cell layer, an encapsulation adhesive layer, and a rear cover plate.

It is further defined that the transparent encapsulation structure includes at least one patterned film layer, the patterned film layer is the patterned adhesive thin film layer, and the patterned adhesive thin film layer has a patterned non-adhesive surface for forming the patterned gap space, and a physical medium layer at a side of the patterned adhesive thin film layer having the patterned non-adhesive surface is a non-adhesive medium layer at a lamination temperature.

It is further defined that the transparent encapsulation structure includes at least one patterned film layer, the patterned film layer is a patterned transparent film layer, the patterned transparent film layer has patterned grooves for forming the patterned gap space, and a physical medium layer at a side where the grooves of the patterned transparent film layer are located is a low-flowing adhesive medium layer.

It is further defined that the optical microstructure includes slots, convex-concave textures or point-mode polyhedrons.

It is further defined that a pattern of the patterned gap space is a sketch pattern, preferably a linear sketch pattern or a pen stipple pattern.

A preparation method of the above photovoltaic module with pattern includes, firstly, preparing the photovoltaic cell layer and various structural layers of an encapsulation structure, and then typesetting and laminating the above layers into a photovoltaic module.

It is further defined that the encapsulation structure includes a transparent encapsulation structure for incident light, the transparent encapsulation structure includes at least one patterned film layer, the patterned film layer is the patterned adhesive thin film layer, the patterned adhesive thin film layer has patterned bubbles for forming the patterned gap space, the physical medium layers at two sides of the patterned adhesive thin film layer are non-flowing or low-flowing medium layers at a lamination temperature, and the bubbles on the patterned adhesive thin film layer are formed by a bubbling or blowing method.

The beneficial effects of the present disclosure are as follows: the principle on which the solution of the present disclosure is based is mainly to change the direction of light rays by means of optical refraction, thus forming color and contrast. The light rays can still contribute to the generation of electricity by the module after changing direction through refraction, so that the power loss is smaller. Through reasonable product design, for example, through the sketch patterning design, the pattern area is reduced to be within 10%, then the power loss can be reduced to be within 2% or even lower.

In order to form strong refraction phenomenon and ensure that an obvious pattern can be observed on the surface of the photovoltaic module, the difference between the refractive index of the patterned region in the module and the refractive index of other encapsulation structures is preferably 0.5 or more. A common dispersion prism or ultra-thin optical glasses lens increases the refractive index of the polymer by a method of doping heavy atom/molecule with a large atomic weight, but this solution will increase the light absorption with reference to the definition of the nature of refractive index in The Feynman Lectures on Physics, volume 1. The present disclosure generates a low refractive index region with a subtraction scheme, namely, by a method of manufacturing gap spaces in the encapsulation structure of the module, and the refractive index can be lower than or equal to 1. The absorption of light by the low refractive index region is low, the refractive index of common transparent encapsulation materials such as PET, EVA or glass is 1.51.6, the refractive index of silicon wafer and SiNx, SiOx, ITO and other materials on the surface of the silicon wafer is 2˜3.5, which makes the refractive index difference between the gap space and the transparent encapsulation materials or photovoltaic cell be 0.5 or more, and larger refractive index differences trigger or enhance the phenomenon of interfacial optical direction changing, which causes the difference in visual perception, and forms an obvious pattern on the surface of the photovoltaic module.

The solution of the present disclosure can manufacture the patterned space gaps through mechanical or laser processing, the manufacturing method is simple, the added cost is extremely low, and artistic culture patterns (such as Han tile lines of the Chinese nation) can be combined on the photovoltaic module to form a good decorative effect.

To sum up, compared with the prior art, the solution of the present disclosure has lower optical loss, simpler manufacturing, lower cost, and better performance, so that it is possible to generate artistic patterns on the surface of the photovoltaic module efficiently at a low cost.

### BRIEF DESCRIPTION OF DRAWINGS

The present disclosure is further described below in combination with drawings and embodiments;

FIG. 1 is a structural schematic view of a photovoltaic module of Embodiment 1 of the present disclosure;

FIG. 2 is a schematic view of a patterned adhesive thin film layer having lines in a shape of Chinese character “ [symbol] ” of Embodiment 1 of the present disclosure;

FIG. 3 shows a pattern of classical pattern a;

FIG. 4 shows a pattern of classical pattern b;

FIG. 5 shows a pattern of classical pattern c;

FIG. 6 shows a pattern of Han dynasty stone relief;

FIG. 7 is a flow block diagram of preparing a patterned composite layer of Embodiment 1 of the present disclosure;

FIG. 8 is a structural schematic view of a transparent film layer having an optical microstructure of Embodiment 2 of the present disclosure;

FIG. 9 is a structural schematic view of a photovoltaic module of Embodiment 3 of the present disclosure;

FIG. 10 is a flow block diagram of typesetting of the photovoltaic module of Embodiment 1 of the present disclosure;

FIG. 11 is a flow block diagram of typesetting of the photovoltaic module of Embodiment 3 of the present disclosure;

FIG. 12 is a flow block diagram of typesetting of a photovoltaic module of Embodiment 4 of the present disclosure; and

FIG. 13 is a partial view of a module trial-manufactured through the technical solution of the present disclosure.

In the drawings, 1. front cover plate, 2. encapsulation adhesive layer, 3-1. transparent film layer, 3-2. patterned adhesive thin film layer, 4. photovoltaic cell layer, 5. rear cover plate, 6. patterned gap space, 7. optical microstructure, 8. through hole.

### DETAILED DESCRIPTION OF EMBODIMENTS

Embodiment 1 As shown in FIGS. 1, 2, 3, 4, 5, 6, 7, and 10, a photovoltaic module with pattern includes a photovoltaic cell layer 4 and a transparent encapsulation structure encapsulating the photovoltaic cell layer 4. The encapsulation structure encapsulating the photovoltaic cell layer 4 of the present Embodiment 1 is a transparent encapsulation structure, not excluding that the encapsulation structure of the photovoltaic cell layer 4 is a non-transparent encapsulation structure, especially for an encapsulation structure on a backside of the photovoltaic cell layer, such as a non-transparent rear cover plate. Patterned gap space 6 is provided inside the transparent encapsulation structure, wherein the patterned gap space 6 has a smaller refractive index than the transparent encapsulation structure, and forms a low refractive index region inside the photovoltaic module, and the refractive index difference between the patterned gap space 6 and physical medium inside the photovoltaic module enables a pattern to be formed on a surface of the photovoltaic module.

The transparent encapsulation structure includes at least one patterned film layer, wherein the patterned film layer is a patterned adhesive thin film layer 3-2, and the patterned adhesive thin film layer 3-2 has patterned through holes 8 for forming the patterned gap space 6; and physical medium layers at two sides of the patterned adhesive thin film layer 3-2 are non-flowing medium layers at a lamination temperature.

Specifically, the low refractive index region, formed by the gap space, of the photovoltaic module with pattern of Embodiment 1 is generated in a place close to the surface of the photovoltaic cell layer 4. The non-flowing medium layer at one side of the patterned adhesive thin film layer 3-2 is the photovoltaic cell layer 4, the non-flowing medium layer at the other side of the patterned adhesive thin film layer 3-2 is a transparent film layer 3-1, and the transparent film layer 3-1 does not have fluidity at 150˜200° C.

The patterned adhesive thin film layer 3-2 is extremely thin, and has a thickness of 5˜200 μm. As the patterned adhesive thin film layer 3-2 is an extremely thin adhesive thin film, although this patterned adhesive thin film layer 3-2 can flow and crosslink during lamination, it is insufficient to fill the patterned through holes 8 on the patterned adhesive thin film layer 3-2. Hence, after lamination, the through holes 8 form the patterned gap space 6 with a low refractive index, providing possibility for incident light to be refracted and change a propagation path.

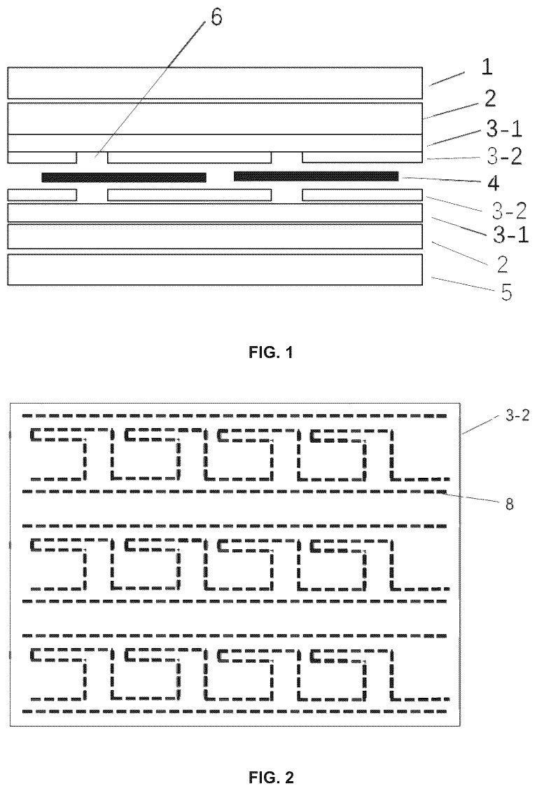

A pattern of the patterned gap space 6 is a sketch pattern, preferably a linear sketch pattern, or a pen stipple pattern. FIG. 2 shows a schematic case. In this drawing, the through holes 8 on the surface of the patterned adhesive thin film layer 3-2 depict a texture in a shape of Chinese character “ [symbol] ” in the Chinese traditional patterns.

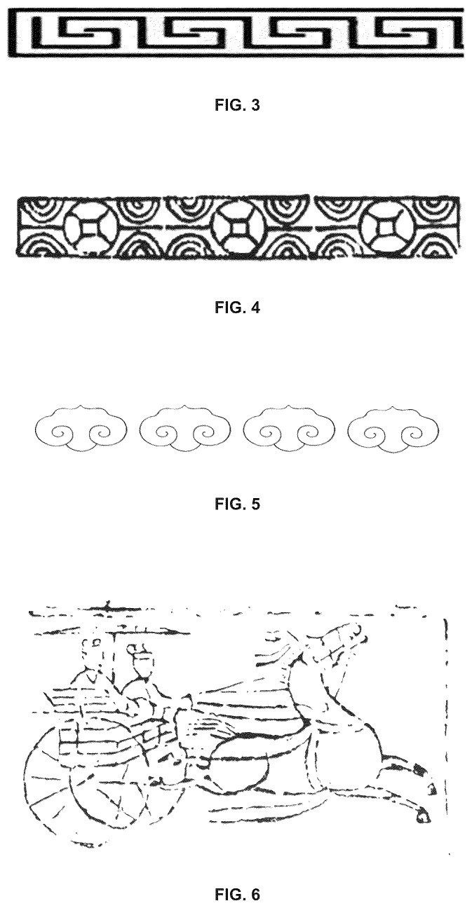

The artistic pattern in FIG. 2 is just an example. In fact, totems and patterns are usually closely linked with the development of national culture. The Qin bricks and Han tiles decorated with patterns are important cultural heritages of Chinese civilization, for example, several typical classical patterns in FIGS. 3˜5 selected from Complete Collection of Chinese Patterns (Shandong Fine Arts Publishing House, 2009) edited by Mr. Wu Shan, and the pattern on Han dynasty stone relief in FIG. 6. Like the texture in a shape of Chinese character “ [symbol] ” in FIG. 2, it is quite easy to manufacture these patterns on a large scale with the method disclosed in the present disclosure. Typical patterns of other nationalities, such as Egyptian patterns, are also well stored in museums around the world, such as French Louvre, and can also be manufactured on a large scale with the solution disclosed in the present disclosure.

As shown in FIG. 1, a specific structure of the photovoltaic module with pattern includes, from top to bottom, a front cover plate 1, an encapsulation adhesive layer 2, a transparent film layer 3-1, a patterned adhesive thin film layer 3-2, a photovoltaic cell layer 4, a patterned adhesive thin film layer 3-2, a transparent film layer 3-1, an encapsulation adhesive layer 2, and a rear cover plate 5. In order to simplify the drawing, a welding strip connecting cell pieces in the photovoltaic cell layer 4 is not drawn in the drawing.

The front cover plate 1 is made of glass, the rear cover plate 5 is made of glass, the encapsulation adhesive layer 2 is made of EVA or POE, the transparent film layer 3-1 is made of PET having no fluidity at 150˜200° C., and the patterned adhesive thin film layer 3-2 is made of EVA. The photovoltaic cells are electrically and mechanically connected as the photovoltaic cell layer 4.

More specifically, the front cover plate 1 and the rear cover plate 5 are made of 2.0 mm tempered glass, the encapsulation adhesive layer 2 is made of POE with a weight of 560 g, the transparent film layer 3-1 is made of PET of 25 μm, the patterned adhesive thin film layer 3-2 is made of EVA of 50 μm, and the photovoltaic cell layer 4 is a heterojunction cell layer.

A preparation method of a photovoltaic module with pattern is as follows: firstly, preparing a photovoltaic cell layer 4 and various structural layers of an encapsulation structure, and then typesetting and laminating the layers into a photovoltaic module.

Specific steps are as follows.

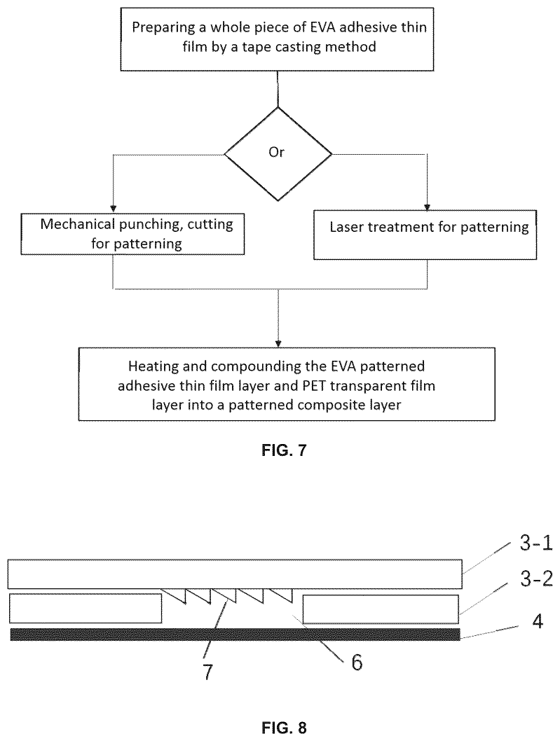

Firstly, the photovoltaic cells are electrically and mechanically connected as the photovoltaic cell layer 4, and a transparent film layer 3-1 and a patterned adhesive thin film layer 3-2 are compounded into a two-layer patterned composite layer, wherein the patterned adhesive thin film layer 3-2 is one adhesive thin film prepared by a tape casting method, and then through holes 8 are made on a surface of the adhesive thin film by a mechanical punching, mechanical cutting or laser treatment method, wherein the through holes 8 are dots or lines, so as to form an artistic pattern on the adhesive thin film, thus realizing the patterning of the adhesive thin film, and obtaining the patterned adhesive thin film layer 3-2, as shown in FIG. 7;
then, as shown in FIG. 10, a front cover plate 1, an encapsulation adhesive layer 2, the patterned composite layer, the photovoltaic cell layer 4, the patterned composite layer, the encapsulation adhesive layer 2, and a rear cover plate 5 are successively laid to complete the typesetting of the photovoltaic module; and
finally, the typeset photovoltaic module enters a laminator to undergo lamination to obtain the photovoltaic module with pattern of the present Embodiment 1.

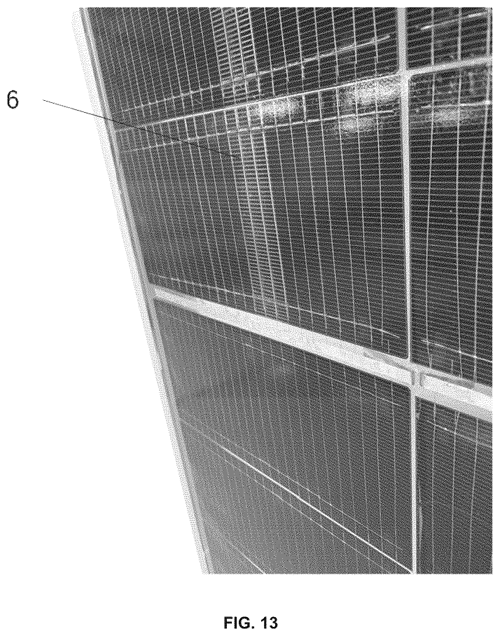

FIG. 13 is a partial view of a photovoltaic module trial-manufactured through the technical solution of the present disclosure. In the photovoltaic module of FIG. 13, a patterned pattern of the patterned gap space 6 is straight stripe, a background color of a surface of the photovoltaic module is a natural color of the module, and the patterned gap space 6 forms a light-colored straight stripe foreground pattern on the surface of the photovoltaic module.

In Embodiment 2, in order to enhance the change of the patterned gap space 6 of Embodiment 1 to the light path, on the basis of Embodiment 1, as shown in FIG. 8, an optical microstructure 7 is formed on a side where light incidence surface of the patterned gap space 6 is located, for enhancing the pattern effect of the surface of the photovoltaic module. Specifically, the optical microstructure 7 is manufactured on a side of the transparent film layer 3-1 facing the patterned adhesive thin film layer 3-2. The optical microstructures 7 are linear slots, convex-concave textures or point-mode polyhedrons, etc., the point-mode polyhedrons are specifically pyramid points, regular hexagonal prisms, etc., and the linear slots are specifically slots of inverted and regular triangular columns, etc. The optical microstructures 7 are distributed on the whole surface or a partial surface of the transparent film layer 3-1, and the partial surface is a surface region corresponding to the patterned gap space 6.

A first method of manufacturing the optical microstructure 7 on the transparent film layer 3-1 is: mechanically sculpting a surface of the transparent film layer 3-1 close to the patterned adhesive thin film layer 3-2, to form linear slots, convex-concave textures or point-mode polyhedrons with specific angles and sizes on the surface.

A second method of manufacturing the optical microstructure 7 on the transparent film layer 3-1 is: coating a layer of polymeric film on the surface of the transparent film layer 3-1 close to the patterned adhesive thin film layer 3-2, then forming the optical microstructure 7 in a manner of embossing or rolling, so as to form linear slots, convex-concave textures or point-mode polyhedrons with a specific angle and size on the surface; and then shaping by hot curing, light curing or other energy curing means.

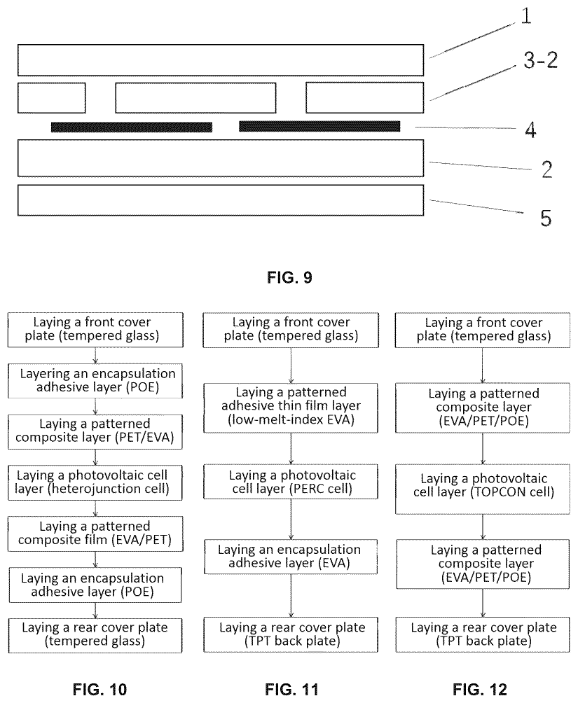

In Embodiment 3, as shown in FIG. 9 and FIG. 11, compared with Embodiment 1, the low refractive index region formed by the gap space of the photovoltaic module with pattern of the present Embodiment 3 is generated in a place close to the surface of the front cover plate 1.

As shown in FIG. 9, a specific structure of the photovoltaic module with pattern includes, from top to bottom, the front cover plate 1, the patterned adhesive thin film layer 3-2, the photovoltaic cell layer 4, the encapsulation adhesive layer 2, and the rear cover plate 5.

Compared with the conventional encapsulation adhesive layer 2, the patterned adhesive thin film layer 3-2 has poorer fluidity at a lamination temperature. This patterned adhesive thin film layer 3-2 is generally a pre-crosslinked polymeric film, a low-melt-index polymeric film or a fiber-reinforced polymeric enhancement film. Through holes 8 can also be made on the surface of the patterned adhesive thin film layer 3-2 by a mechanical punching, mechanical cutting or laser treatment method, realizing the patterning.

More specifically, the front cover plate 1 is made of 3.2 mm tempered glass, the patterned adhesive thin film layer 3-2 is made of low-melt-index EVA with a weight of 560 g, the photovoltaic cell layer 4 is made of a PERC cell layer, the encapsulation adhesive layer 2 is made of conventional EVA with a weight of 560 g, and the rear cover plate 5 is a TPT back plate.

Specific steps of the preparation method of the photovoltaic module with pattern are as follows:
firstly, the photovoltaic cell layer 4 and various structural layers of an encapsulation structure are prepared;
then, as shown in FIG. 11, the front cover plate 1, the encapsulation adhesive layer 2, the patterned adhesive thin film layer 3-2, the photovoltaic cell layer 4, the encapsulation adhesive layer 2, and the rear cover plate 5 are successively laid to complete the typesetting of the photovoltaic module; and
finally, the typeset photovoltaic module enters a laminator to undergo lamination to obtain the photovoltaic module with pattern of the present Embodiment 3.

In Embodiment 4, compared with Embodiment 3, an optical microstructure 7 is manufactured on a lower surface of the front cover plate 1 of a glass material on the basis of Embodiment 3, and the optical microstructure 7 may be simply formed in the process of glass rolling and embossing.

Embodiment 5 is a second solution of forming the low refractive index region by the gap space in a place close to the surface of the front cover plate 1. Embodiment 5 is substantially the same as Embodiment 1, and differs in that: a specific structure of the photovoltaic module with pattern includes, from top to bottom, the front cover plate 1, the patterned adhesive thin film layer 3-2, the transparent film layer 3-1, the encapsulation adhesive layer 2, the photovoltaic cell layer 4, the patterned adhesive thin film layer 3-2, the transparent film layer 3-1, the encapsulation adhesive layer 2, and the rear cover plate 5.

The front cover plate 1 is made of 3.2 mm tempered glass, the patterned adhesive thin film layer 3-2 is made of EVA of 50 nm, the transparent film layer 3-1 is made of PET of 25 nm, the encapsulation adhesive layer 2 is made of POE with a weight of 560 g, and the photovoltaic cell layer 4 is a TOPCON cell layer.

The patterned adhesive thin film layer 3-2, the transparent film layer 3-1, and the encapsulation adhesive layer 2 are compounded into a three-layer patterned composite layer for typesetting and lamination.

As shown in FIG. 12, the typesetting step is: successively laying the front cover plate 1, the patterned composite layer, the photovoltaic cell layer 4, the patterned composite layer, and the rear cover plate 5 to complete the typesetting of the photovoltaic module.

Embodiment 6, substantially the same as Embodiment 1, differs in that the rear cover plate 5 is a TPT back plate.

The typesetting step is: successively laying 2.0 mm tempered glass, POE with a weight of 560 g/m2, the patterned composite layer compounded by two layers of EVA and PET in Embodiment 1, a heterojunction photovoltaic cell layer 4, the patterned composite layer compounded by two layers of EVA and PET in Embodiment 1, POE with a weight of 560 g/m2, and the TPT back plate, to complete the typesetting of the photovoltaic module.

Embodiment 7, substantially the same as Embodiment 1, differs in that the patterned film layer is a patterned transparent film layer, the patterned transparent film layer has a patterned groove for forming the patterned gap space 6, and a physical medium layer at one side of the groove of the patterned transparent film layer is a low-flowing adhesive medium layer.

Specifically, the patterned transparent film layer is specifically the front cover plate 1 in the encapsulation structure, and the patterned groove is fabricated on a lower surface of the front cover plate 1 facing the photovoltaic cell layer 4.

A specific structure of the photovoltaic module with pattern includes, from top to bottom, the patterned front cover plate 1, the encapsulation adhesive layer 2, the photovoltaic cell layer 4, the encapsulation adhesive layer 2, and the rear cover plate 5.

The encapsulation adhesive layer 2 is a pre-crosslinked polymeric film, a low-melt-index polymeric film or a fiber-reinforced polymeric enhancement film, and belongs to a low-flowing adhesive medium layer with poor fluidity, and in a lamination process, the encapsulation adhesive layer 2 will not fill in the patterned groove on the patterned adhesive thin film layer 3-2.

Embodiment 8, substantially the same as Embodiment 1, differs in that: the encapsulation structure includes a transparent encapsulation structure for light incidence, and the transparent encapsulation structure includes a patterned film layer, wherein the patterned film layer is the patterned adhesive thin film layer 3-2, the patterned adhesive thin film layer 3-2 has patterned bubbles for forming the patterned gap space 6, the physical medium layers at two sides of the patterned adhesive thin film layer 3-2 are non-flowing or low-flowing medium layers at a lamination temperature, and the bubbles on the patterned adhesive thin film layer 3-2 are formed by a bubbling or blowing method.

A specific structure of the photovoltaic module with pattern includes, from top to bottom, the front cover plate 1, the patterned adhesive thin film layer 3-2, the photovoltaic cell layer 4, the encapsulation adhesive layer 2, and the rear cover plate 5.

An encapsulation adhesive material having low fluidity, such as a pre-crosslinked film, a low-melt-index film, or a fiber-reinforced film, is selected as the patterned adhesive thin film layer 3-2, and during the process of tape casting or coating manufacturing, the bubbles are formed in the patterned adhesive thin film layer 3-2 in a manner of bubble doping, to realize the patterning. The manner of bubble doping includes bubble doping manners such as bubbling and blowing. Meanwhile, the patterned adhesive thin film layer 3-2 is non-uniformly cured by a method with plasma, heat, light, electromagnetic waves, or the like alternatively or in combination, and the physical medium layers at the two sides of the patterned adhesive thin film layer 3-2 are non-flowing or low-flowing medium layers at a lamination temperature. The two manners ensure that the patterned adhesive thin film layer 3-2 will not disappear as being filled with other medium layer materials during the lamination process.

A specific method of bubble doping in a bubbling manner is: in the process of tape casting or coating manufacturing, selectively adding a bubbling agent (foaming agent) into different regions of the material of the patterned adhesive thin film layer 3-2, and controlling the concentration of the bubbling agent according to the patterning requirements, wherein the higher the concentration of the bubbling agent is, the more the bubbles are generated, and the more the patterned gap spaces 6 are formed, and the lower the concentration of the bubbling agent is, the fewer the bubbles are generated, and the fewer the patterned gap spaces 6 are formed, and according to the principle of sketch, a sketch pattern will be formed on the surface of the photovoltaic module.

Specific steps of a preparation method of the photovoltaic module with pattern of Embodiment 8 are as follows:
firstly, photovoltaic cells are electrically and mechanically connected into the photovoltaic cell layer 4, and during the process of tape casting or coating manufacturing of an adhesive thin film material of the patterned adhesive thin film layer 3-2, the bubbling agent is selectively added in different regions;
then, the front cover plate 1, the adhesive thin film material added with the bubbling agent, the photovoltaic cell layer 4, the encapsulation adhesive layer 2, and the rear cover plate 5 are successively laid, to complete the typesetting of the photovoltaic module; and
Finally, the typeset photovoltaic module enters a laminator to undergo lamination, and the bubbling agent generates bubbles at a lamination temperature, so that the adhesive thin film material added with the bubbling agent is patterned, and the adhesive thin film material added with the bubbling agent is formed into the patterned adhesive thin film layer 3-2, to obtain the photovoltaic module with pattern of the present Embodiment 8.

Embodiment 9, substantially the same as Embodiment 1, differs in that the transparent encapsulation structure includes at least one patterned film layer, the patterned film layer is the patterned adhesive thin film layer 3-2, and the patterned adhesive thin film layer 3-2 has a patterned non-adhesive surface for forming the patterned gap space 6. A physical medium layer at a side of the patterned adhesive thin film layer 3-2 with the patterned non-adhesive surface is a non-adhesive medium layer at a lamination temperature.

A specific structure of the photovoltaic module with pattern includes, from top to bottom, the front cover plate 1, the patterned adhesive thin film layer 3-2, the photovoltaic cell layer 4, the encapsulation adhesive layer 2, and the rear cover plate 5.

The patterned adhesive thin film layer 3-2 is non-uniformly cured by a method with plasma, heat, light, electromagnetic waves or the like, to realize the patterning of the patterned adhesive thin film layer 3-2, and specifically the laser is preferred as a patterning processing workpiece. The adhesive thin film material of the patterned adhesive thin film layer 3-2 will be non-uniformly cured under the action of laser, to form a non-adhesive surface, and the patterned gap space 6 will be formed between the non-adhesive surface and the front cover plate 1 after the typesetting and lamination.

By adjusting the laser parameters, the curing degree of the adhesive thin film material of the patterned adhesive thin film layer 3-2 can be adjusted. Different curing degree leads to different adhesive property. Laser grooving and poring can also be realized by the laser.

Embodiment 10, substantially the same as Embodiment 1, differs in that in Embodiment 1, the transparent film layer 3-1 and the patterned adhesive thin film layer 3-2 are directly compounded by hot pressing, while in the present Embodiment 10, the transparent film layer 3-1 and the patterned adhesive thin film layer 3-2 are bonded and compounded by an adhesive to form a patterned composite layer.

1. A photovoltaic module with pattern, comprising a photovoltaic cell layer and a transparent encapsulation structure encapsulating the photovoltaic cell layer, wherein a patterned gap space is provided inside the transparent encapsulation structure for forming a low refractive index region, and refractive index difference between the patterned gap space and a physical medium inside the photovoltaic module enables a pattern to be formed on a surface of the photovoltaic module.

2. The photovoltaic module with pattern according to claim 1, wherein the transparent encapsulation structure comprises at least one patterned film layer, wherein the patterned film layer has patterned through holes, grooves or bubbles for forming the patterned gap space.

3. The photovoltaic module with pattern according to claim 1, wherein a side of the patterned gap space has an optical microstructure, for enhancing a pattern effect of the surface of the photovoltaic module.

4. The photovoltaic module with pattern according to claim 1, wherein the transparent encapsulation structure comprises at least one patterned film layer, wherein the patterned film layer is a patterned adhesive thin film layer, the patterned adhesive thin film layer has patterned through holes, grooves or bubbles, for forming the patterned gap space, and physical medium layers at two sides of the patterned adhesive thin film layer are non-flowing or low-flowing medium layers at a lamination temperature.

5. The photovoltaic module with pattern according to claim 4, wherein a physical medium layer at a side where a light incident surface of the patterned adhesive thin film layer is located is a non-flowing medium layer, an optical microstructure is provided on a side of the non-flowing medium layer facing the patterned adhesive thin film layer, the optical microstructure is distributed on a whole surface or a partial surface of the non-flowing medium layer, and the partial surface is a surface region corresponding to the patterned gap space.

6. The photovoltaic module with pattern according to claim 4, wherein the patterned adhesive thin film layer has a thickness of 5˜200 μm.

7. The photovoltaic module with pattern according to claim 4, wherein the patterned adhesive thin film layer has one side provided with the photovoltaic cell layer, and the other side provided with a transparent film layer.

8. The photovoltaic module with pattern according to claim 4, wherein a specific structure comprises, from top to bottom, a front cover plate, an encapsulation adhesive layer, a transparent film layer, the patterned adhesive thin film layer, the photovoltaic cell layer, the patterned adhesive thin film layer, the transparent film layer, the encapsulation adhesive layer, and a rear cover plate; or
a specific structure comprises, from top to bottom, a front cover plate, an encapsulation adhesive layer, a transparent film layer, the patterned adhesive thin film layer, the photovoltaic cell layer, the encapsulation adhesive layer, and a rear cover plate; or
a specific structure comprises, from top to bottom, a front cover plate, the patterned adhesive thin film layer, the photovoltaic cell layer, the patterned adhesive thin film layer, and a rear cover plate; or
a specific structure comprises, from top to bottom, a front cover plate, the patterned adhesive thin film layer, the photovoltaic cell layer, an encapsulation adhesive layer, and a rear cover plate.

9. The photovoltaic module with pattern according to claim 1, wherein the transparent encapsulation structure comprises at least one patterned film layer, wherein the patterned film layer is the patterned adhesive thin film layer, and the patterned adhesive thin film layer has a patterned non-adhesive surface for forming the patterned gap space, and a physical medium layer at a side of the patterned adhesive thin film layer having the patterned non-adhesive surface is a non-adhesive medium layer at a lamination temperature.

10. The photovoltaic module with pattern according to claim 1, wherein the transparent encapsulation structure comprises at least one patterned film layer, the patterned film layer is a patterned transparent film layer, the patterned transparent film layer has patterned grooves for forming the patterned gap space, and a physical medium layer at a side where the grooves of the patterned transparent film layer are located is a low-flowing adhesive medium layer.

11. The photovoltaic module with pattern according to claim 3, wherein the optical microstructure comprises slots, convex-concave textures or point-mode polyhedrons.

12. The photovoltaic module with pattern according to claim 1, wherein a pattern of the patterned gap space is a sketch pattern.

13. A preparation method of the photovoltaic module with pattern according to claim 1, comprising firstly, preparing the photovoltaic cell layer and various structural layers of the encapsulation structure, and then typesetting and laminating these layers into the photovoltaic module.

14. The preparation method of the photovoltaic module with pattern according to claim 13, wherein the encapsulation structure comprises a transparent encapsulation structure for light incidence, the transparent encapsulation structure comprises at least one patterned film layer, the patterned film layer is the patterned adhesive thin film layer, the patterned adhesive thin film layer has patterned bubbles for forming the patterned gap space, physical medium layers at two sides of the patterned adhesive thin film layer are non-flowing or low-flowing medium layers at a lamination temperature, and the bubbles on the patterned adhesive thin film layer are formed by a bubbling or blowing method.

15. The photovoltaic module with pattern according to claim 5, wherein the patterned adhesive thin film layer has a thickness of 5˜200 μm.

16. The photovoltaic module with pattern according to claim 5, wherein the patterned adhesive thin film layer has one side provided with the photovoltaic cell layer, and the other side provided with a transparent film layer.

17. The photovoltaic module with pattern according to claim 5, wherein a specific structure comprises, from top to bottom, a front cover plate, an encapsulation adhesive layer, a transparent film layer, the patterned adhesive thin film layer, the photovoltaic cell layer, the patterned adhesive thin film layer, the transparent film layer, the encapsulation adhesive layer, and a rear cover plate; or
a specific structure comprises, from top to bottom, a front cover plate, an encapsulation adhesive layer, a transparent film layer, the patterned adhesive thin film layer, the photovoltpaic cell layer, the encapsulation adhesive layer, and a rear cover plate; or
a specific structure comprises, from top to bottom, a front cover plate, the patterned adhesive thin film layer, the photovoltaic cell layer, the patterned adhesive thin film layer, and a rear cover plate; or
a specific structure comprises, from top to bottom, a front cover plate, the patterned adhesive thin film layer, the photovoltaic cell layer, an encapsulation adhesive layer, and a rear cover plate.

18. The photovoltaic module with pattern according to claim 5, wherein the optical microstructure comprises slots, convex-concave textures or point-mode polyhedrons.
